(19) United States
(12) Patent Application Publication
(10) Pub. No.: US 2002/0038899 A1
(43) Pub. Date: Apr. 4, 2002

(54) SEMICONDUCTOR DEVICE WITH TELERANCE TO PATTERN DISPLACEMENT

(76) Inventor: SATOSHI YAMAGUCHI, TOKYO (JP)

Correspondence Address: SUGHRUE MION ZINN MACPEAK & SEAS, 2100 PENNSYLVANIA AVENUE NW, WASHINGTON, DC, 20037

(21) Appl. No.: 09/418,555

(22) Filed: Oct. 14, 1999

(30) Foreign Application Priority Data
Oct. 20, 1998 (JP) 298375/98

(51) Int. Cl. H01L 21/336; H01L 29/76; H01L 31/062; H01L 21/4763

(52) U.S. Cl. 257/401; 438/197; 438/585; 438/587; 257/368; 257/288

(57) ABSTRACT

A semiconductor device includes first and second transistors to be arranged a point symmetry with respect to a point and having first and second gates and first and second channel regions, respectively. The first and second gates are formed based on first and second gate electrode patterns to be arranged a point symmetry with respect to the point, respectively. Each of the first and second gate electrode patterns includes first and second serif sections and an electrode section between the first and second serif sections.

### BACKGROUND OF THE INVENTION

1. Field of the Invention

The present invention relates to a semiconductor device and a method of manufacturing the same. More particularly, the present invention is directed to a semiconductor device formed not to lose the reliability of a circuit operation, even if patterns are displaced.

2. Description of the Related Art

In a semiconductor integrated circuit, many field effect transistors are used to form pairs of transistors in circuits such as a flip-flop circuit, a sense amplifier circuit in a memory device, and a memory cell circuit of a static random access memory (SRAM). Such a transistor is referred to as a pair transistor, hereinafter. The difference between the pair transistors in characteristic influences to the yield of the integrated circuit, the efficiency thereof, and the characteristic deviation.

FIG. 1 shows a plane layout of a memory cell of an SRAM as an example of the integrated circuits using pairs transistors. In the figure, channel regions 105 and 107 of a driver transistor 101 and access transistor 103 and a diffusion layer 109 are formed in an active region 111 which is defined by a field oxide film. Also, channel regions 106 and 108 of a driver transistor 102 and access transistor 104 and a diffusion layer 110 are formed in another active region 112.

The diffusion layer 109 is used in common to the drain region of the driver transistor 101 and the source/drain region of the access transistor 103. The diffusion layer 110 is used in common to the source/drain region of the driver transistor 102 and the access transistor 104. The diffusion layer 109 is connected with the gate electrode 116 of the driver transistor 102 through a contact 113. The diffusion layer 110 is connected with the gate electrodes 115 and 116 of the driver transistor 101 through a contact 114. One of the source/drain regions of the access transistors 103 and 104 are connected with a bit line (not shown) through contact holes 117 and 118, respectively. Also, the gate electrodes 119 and 120 of the access transistors 103 and 104 are used as a word line of the memory cells. Serif sections 121 and 122 are formed at ends of the gate electrodes 115 and 116, and serif sections 123 and 124 are formed at the other ends.

FIG. 2 is a diagram showing an equivalent circuit of the SRAM memory cell of FIG. 1. In the SRAM memory cell of FIG. 1, a flip-flop 125 storing data of 1/0 is connected with bit lines 128 and 129 through the access transistors 103 and 104, respectively.

The drains (or sources) of the access transistors 103 and 104 are connected with the bit lines 128 and 129, respectively. The sources (or the drains) of the access transistors 103 and 104 are connected with the drains of the driver transistors 101 and 102, respectively. The access transistors 103 and 104 carry out the connection or disconnection between the flip-flop 125 and the bit lines 128 and 129 in accordance with the voltage level of the word line 131.

The structure of the flip-flop 125 is as follows. the driver transistors 101 and 102 are both grounded in the sources. A gate of one of the driver transistors 101 and 102 is connected with the drain of the other transistor. The drains of the driver transistors 101 and 102 are connected with the common power supply voltage terminal 130 through the resistors 126 and 127. This circuit has two stable states and the flip-flop 125 stores 1/0 data using these two stable states.

It is desirable that the driver transistors 101 and 102 of the flip-flop 125 have the same characteristics. If the transistors 101 and 102 does not have the same characteristics, the reliability of the operation is lost, because the asymmetry occurs between to the “1” storing operation and the “0” storing operation. When the characteristic difference between the transistors is large exceedingly, the data cannot be stored.

It is supposed that the SRAM having the layout of the memory cell shown in FIG. 1 is actually manufactured. In this case, the memory cell has patterns as shown in FIG. 3 (In the figure, the same reference numerals are allocated to the same components as shown in FIG. 1). As shown in FIG. 3, the pattern is rounded the corner section due to a photo-lithography process. At this time, as shown in FIG. 4, when alignment displacement is caused between diffusion layers 109 and 110 and gate electrodes 115 and 116 into a vertical direction (y direction), i.e., into the longitudinal direction of the gate electrodes 115 and 116 of the driver transistors 101 and 102, the shapes of the channel regions 105 and 106 of the driver transistors 101 and 102 become different. Therefore, when the alignment displacement occurs, a difference is generated between the drive transistors 101 and 102 in characteristic.

It is not desirable that the difference is generated between the device transistors in characteristic, because the reliability of the operation of the memory cell is lost, as described above. In the semiconductor device with very fine patterns, influence of the alignment displacement is large and this problem is more serious. The problem that the characteristic difference is generated between pair transistors due to the alignment displacement is serious in semiconductor devices with a pair transistor circuit such as a sense amplifier in addition to the SRAM memory cell.

Conventionally, in Japanese Laid Open Patent Application (JP-A-Heisei 8-241929) is known a semiconductor device. In this reference, active regions are formed in a point symmetry or line symmetry in the neighborhood of the channel region of the driver transistor, or the word lines are formed in a point symmetry or a line symmetry in the neighborhood of the channel region of the access transistor. In this way, even if a relative position difference is caused between the gate electrode and the active region, the channel regions are kept to have substantially the same shape, resulting in compensation of the characteristic difference between the pair transistors.

In this semiconductor device, the relation of the channel regions can be kept against the alignment displacement in the traverse direction (x direction), as shown in FIG. 5. However, as shown in FIG. 6, when the position alignment displacement is caused in the y direction in the semiconductor device, the channel regions 105 and 106 of the driver transistors 101 and 102 are formed to have different shapes so that the reliable operation can not be maintained.

Also, the arrangement of layout of a semiconductor device is disclosed in Japanese Laid Open Patent Application (JP-A-Heisei 3-142875). In this reference, the characteristic difference is not generated between two transistors, even if the alignment displacement is caused. In this reference, wiring patterns between the two transistors are intersected so that the transistors are arranged in the same direction. Thus, the generation of the characteristic difference between the transistors due to the alignment displacement is prevented. In this reference, the shape of the source or drain region can be kept to be same between the two transistors, so that the drain or source resistance of the two transistors can be made identical. However, the reference has no effect against the alignment displacement which causes the difference between the shapes of the channel regions of the transistors.

### SUMMARY OF THE INVENTION

Therefore, an object of the present invention is to provide a semiconductor device which has pair transistors with the same characteristics by compensating position alignment displacement of gate electrodes of the pair transistors.

Another object of the present invention is to provide an SRAM having stable operation.

Still another object of the present invention is to provide a semiconductor device having wide tolerance to position alignment displacement of the gate electrodes of pair transistors.

In order to achieve an aspect of the present invention, a semiconductor device includes first and second transistors to be arranged a point symmetry with respect to a point and having first and second gates and first and second channel regions, respectively. The first and second gates are formed based on first and second gate electrode patterns to be arranged a point symmetry with respect to the point, respectively. Each of the first and second gate electrode patterns includes first and second serif sections and an electrode section between the first and second serif sections.

Here, it is preferable that the first and second electrode sections have substantially a same width in a direction perpendicular to a longitudinal direction of each of the first and second gate electrode patterns. In this case, a distance from the first serif section to the first channel region in the first gate electrode pattern is preferably substantially the same as a distance from the first serif section to the second channel region in the second gate electrode pattern. Also, a distance from the second serif section to the first channel region in the first gate electrode pattern is preferably substantially the same as a distance from the second serif section to the second channel region in the second gate electrode pattern.

Also, the first serif section and the second serif section may have substantially the same width in each of the first and second gate electrode patterns. Also, the first serif section and the second serif section have substantially the same shape in each of the first and second gate electrode patterns.

In order to achieve another aspect of the present invention, a static random the access memory includes a flip-flop including first and second transistors electrically cross-connected. The first and second transistors are arranged a point symmetry with respect to a point and have first and second gates and first and second channel regions, respectively. The first and second gates are formed based on first and second gate electrode patterns to be arranged a point symmetry with respect to the point, respectively. Each of the first and second gate electrode patterns includes first and second serif sections and an electrode section between the first and second serif sections. The first serif in one of the first and second transistors corresponding to one of the first and second gate electrode patterns is connected to a source/drain region of the other of the first and second transistors.

In order to achieve still another aspect of the present invention, a method of manufacturing a semiconductor devices, includes:

forming a first and second diffusion regions on a semiconductor substrate using a first mask;

forming an insulating film on the semiconductor substrate as a gate insulating film; and

forming first and second gate electrodes patterns using a second mask such that first and second transistors are formed based on the first and second gate electrodes patterns and the first and second diffusion regions, respectively. In this case, each of the first and second gate electrode patterns includes first and second serif sections and an electrode section between the first and second serif sections.

### BRIEF DESCRIPTION OF THE DRAWINGS

FIG. 1 is an example of a plane layout of an SRAM as a conventionally semiconductor device;

FIG. 2 is a diagram showing an equivalent circuit of the SRAM shown in FIG. 1;

FIG. 3 is a diagram showing a memory cell of the SRAM shown in FIG. 1 when the memory cell is actually manufactured without any position alignment displacement;

FIG. 4 is a diagram showing the memory cell when the memory cell is manufactured with any position alignment displacement;

FIG. 5 is a diagram showing the layout of a memory cell of another conventional example of a semiconductor device;

FIG. 6 is a diagram showing the memory cell of the other conventional example of the semiconductor device when the memory cell is manufactured with any position alignment displacement in a longitudinal direction of a gate electrode;

FIG. 7 is a plane layout diagram of a memory cell of an SRAM such as a semiconductor device according to a first embodiment of the present invention;

FIG. 8 is a diagram showing the memory cell of FIG. 7 when the memory cell is actually manufactured without any position alignment displacement;

FIG. 9 is a diagram showing the memory cell of FIG. 7 when the memory cell is manufactured with a position alignment displacement in a longitudinal direction of a gate electrode pattern;

FIGS. 10A to 10E are cross sectional views of the semiconductor device manufactured based on a method according to the first embodiment of the present invention;

FIG. 11A is a mask layout of the first mask to determine the shape of an active region;

Fig. 11B is a mask layout of the second mask to determine the shape of the first conductive layer;

FIG. 12 is a plane layout diagram showing of a memory cell of the semiconductor device according to the second embodiment of the present invention;

FIG. 13 is a diagram showing the memory cell of the semiconductor device when the memory cell is actually manufactured without any position alignment displacement; and

FIG. 14 is a diagram showing the memory cell when the memory cell is manufactured with a position alignment displacement.

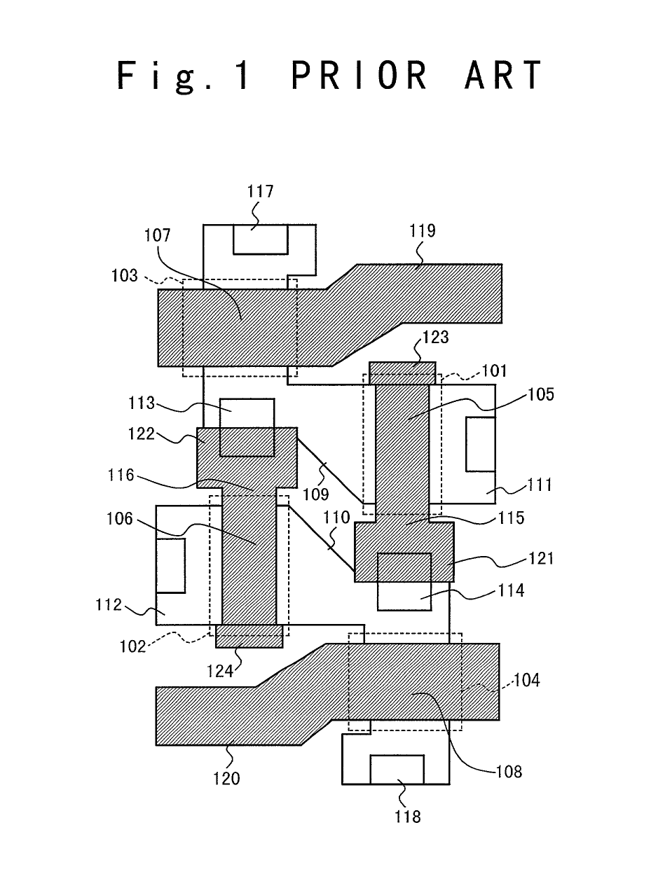

### DESCRIPTION OF THE PREFERRED EMBODIMENTS

A semiconductor device of the present invention will be described below in detail with reference to the attached drawings. Various semiconductor device have pair transistors. In the following description, an SRAM with a memory cell is taken as an example of the semiconductor device.

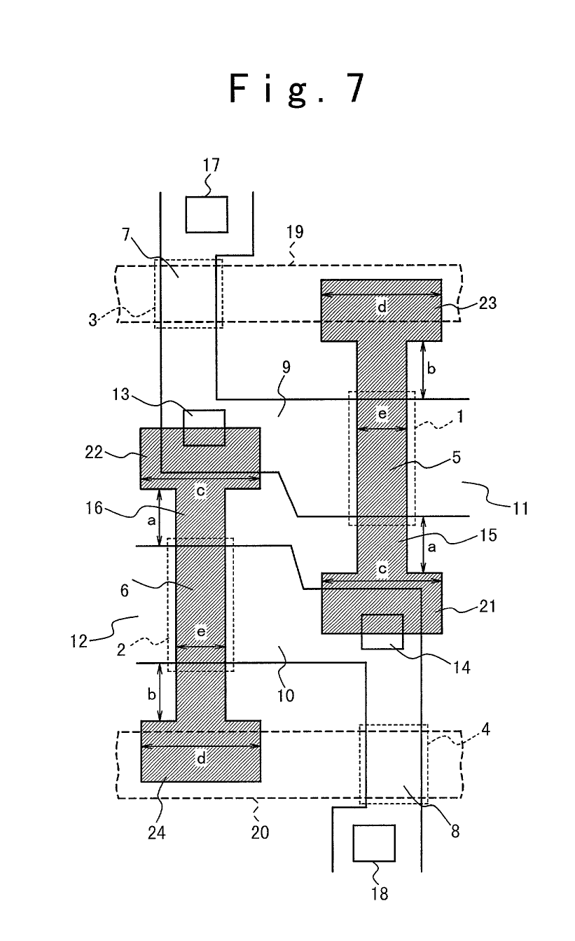

FIG. 7 is a diagram showing a plane layout of the memory cell of the SRAM according to the first embodiment of the present invention. The SRAM memory cell shown in FIG. 7 is composed of driver transistors 1 and 2 and access transistors 3 and 4. Diffusion layers 9 and channel regions of the driver transistor 1 and access transistor 3 are formed in an active region 11 which is segmented by a field oxide film. Diffusion layer 10 and channel regions of the driver transistor 2 and access transistor 4 are formed in an active region 12.

The diffusion layer 9 is used for the drain region of the driver transistor 1 and the source/drain region of the access transistor 3. Also, the diffusion layer 10 is used for the source/drain regions of the driver transistor 2 and access transistor 4.

The gate electrodes 15 and 16 of the driver transistors 1 and 2 are formed of a first conductive layer, e.g., a polysilicon layer. The gate electrode 15 of the driver transistor 1 is connected with the diffusion layer 10 through a contact 14. The gate electrode 16 of the driver transistor 2 is connected with the diffusion layer 9 through a contact 13. One of the source/drain regions of the access transistors 3 and 4 are connected with bit lines (not shown) through contact holes 17 and 18, respectively. Also, the gate electrodes 19 and 20 of the access transistors 17 and 18 are formed of film of a second conductive layer, e.g., a laminate conductive layer of a polysilicon layer and a tungsten silicide layer, and are used for a word line of the memory cells. The gate electrodes 15 and 16 and the gate electrodes 19 and 20 are formed of different conductive layers, and the gate electrodes 19 and 20 are formed on the gate electrodes 15 and 16 via an interlayer insulating film to have overlapping portions. At the one end of each of the gate electrodes 15 and 16, first serif sections 21 and 22 are formed to have the width of c, and at the other end, second serif sections 23 and 24 are formed to have the width of d. The first serif sections 21 and 22 are necessary to secure a margin to the position alignment displacement when the contact holes 13 and 14 are formed to connect the diffusion layers 9 and 10 to the gate electrodes 16 and 15, respectively.

Because the size of the first serif section 21 or 22 is changed depending on the layout and the manufacturing method, the size cannot be preliminarily determined. The size of the first serif section 21 or 22 is determined based on parameters such as the size of the contact hole 13 or 14 and the margin of the position alignment displacement between the contact hole 13 or 14 and the gate electrode 15 or 16, and a distance between the diffusion layers 9 and 10.

The second serif sections 23 or 24 is formed to have the width d larger than the channel length e such that the gate width does not become narrow when the gate electrode is formed through an etching process. In this embodiment, the width d of the second serif section 23 or 24 is made equal to the width c of the first serif section 21 or 22. Also, in this embodiment, the distance a from the first serif section 21 to the channel region 5 of the driver transistor 1 is made substantially equal to the distance b from the second serif section 24 to the channel region 6 of the driver transistor 2. In the same way, the distance a from the first serif section 22 to the driver transistor 2 is made substantially equal to the distance b from the second serif section 23 to the driver transistor 1. In this way, one feature of the first embodiment of the present invention is in that the above-mentioned distances a and b are equal to each other and the width c of first serif section 13 or 14 and the width d of the second serif section 15 or 16 are equal to each other.

It is desirable that the first serif sections 21 and 22 and the second serif sections 23 and 24 are to have not only the same width but also substantively the same shape. Therefore, in the example shown in FIG. 7, the first serif sections 21 and 22 have the same shape as the second serif sections 23 and 24. When the shapes of first serif sections 21 and 22 are substantially the same as those of the second serif sections 23 and 24, the gate electrodes 23 and 24 can be formed to have the more symmetrical shapes above the active regions 1 and 2. In the above example, because the width c of first serif sections 21 or 22 is substantially the same as the width d of the second serif sections 23 or 24, the characteristic difference is not generated between the driver transistors 1 and 2.

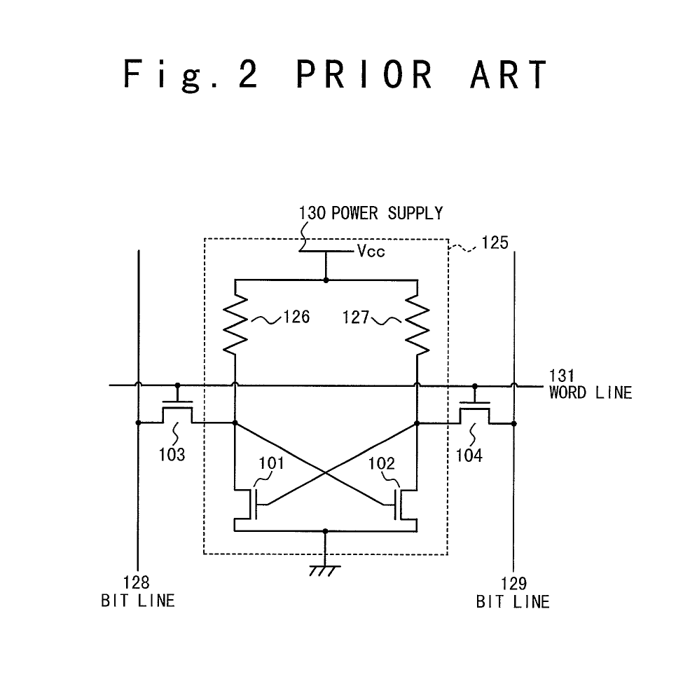

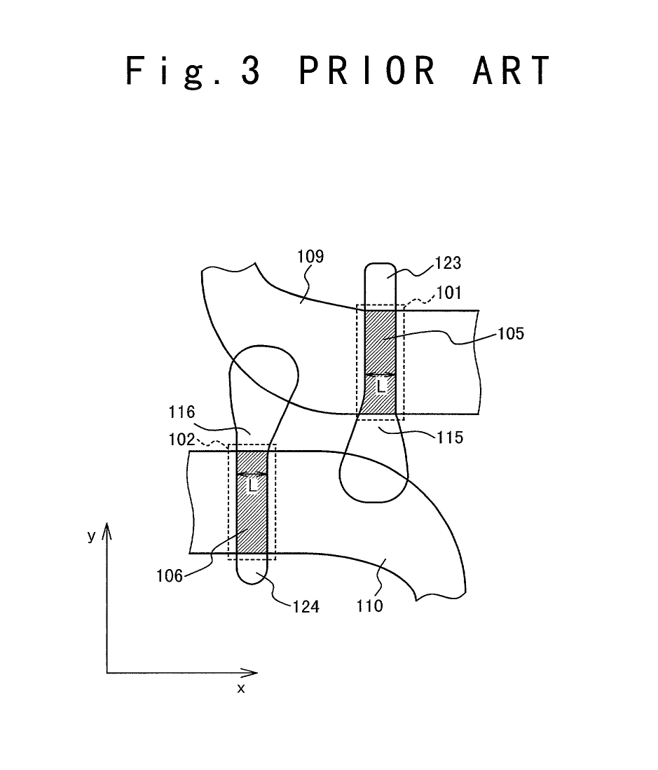

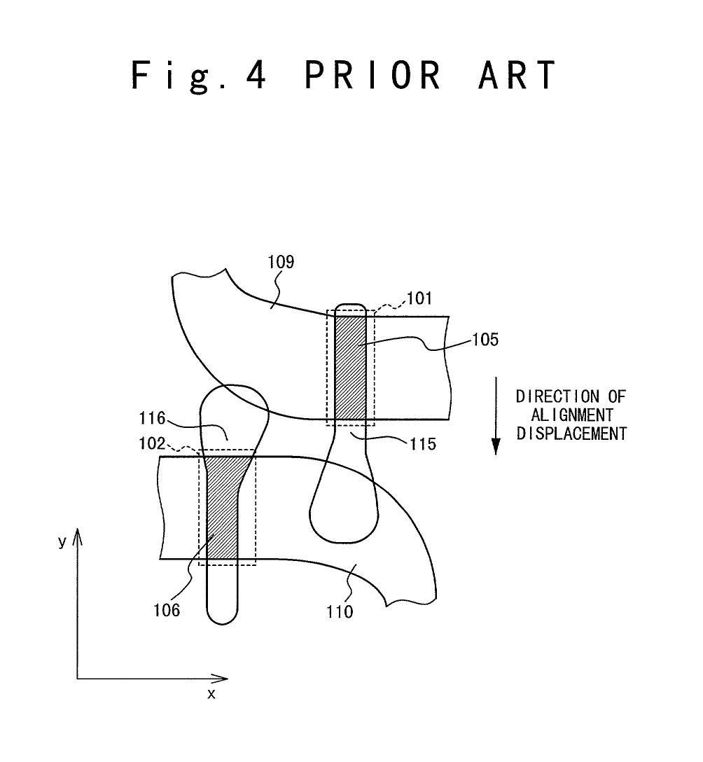

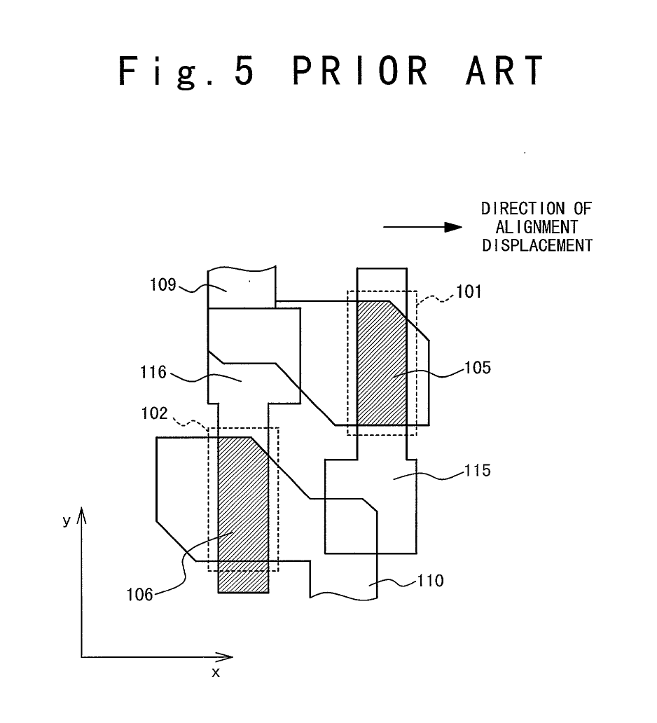

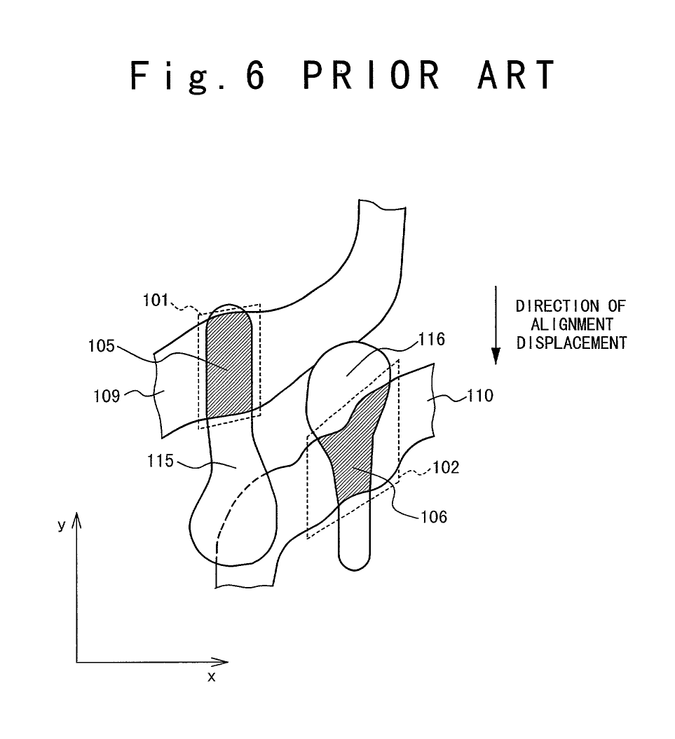

The equivalent circuit of the example shown in FIG. 7 is the same as that shown in FIG. 2 and the operation thereof is the same as the operation of the SRAM memory cell shown in FIG. 2.

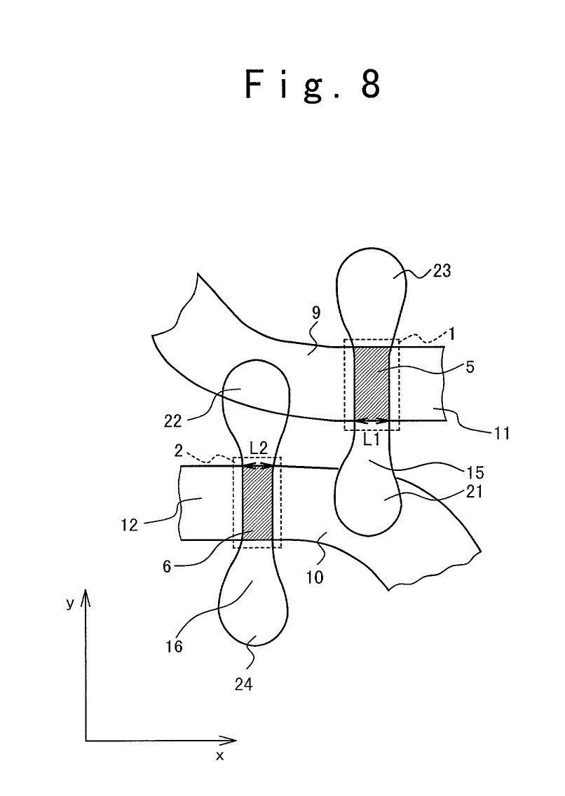

When the SRAM is manufactured based on the memory cell layout shown in FIG. 7, the memory cell has the shape as shown in FIG. 8. In the figure, the same components are allocated with the same numerals as those in FIG. 7. Because the pattern is rounded at the corner due to a lithography process, the first serif sections 21 and 22 and the second serif sections 23 and 24 are formed round at each corner section. However, as seen from FIG. 8, the maximum widths L1 and L2 of the channel regions 5 and 6 of the driver transistors 1 and 2 are same. This is because the distances a from the first serif sections 21 and 22 to the driver transistors 1 and 2 are equal to the distances b from the second serif sections 24 and 23 to the driver transistors 2 and 1. Also, it is because the widths c of first serif sections 21 and 22 and the widths d of the second serif sections 23 and 24 are same.

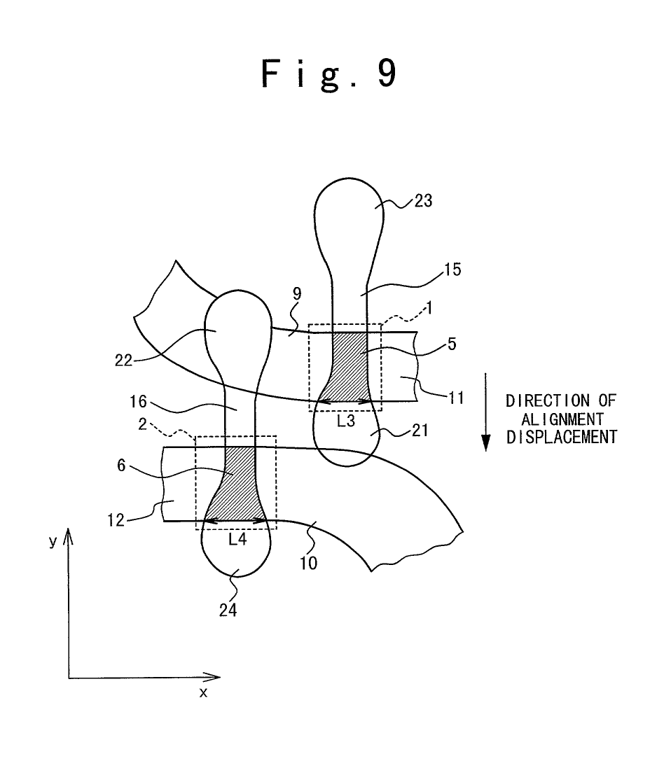

FIG. 9 shows the shape of the SRAM memory cell when the position alignment displacement between the diffusion layers 9 and 10 and the gate electrodes 15 and 16 is caused in the longitudinal direction or the y direction shown in FIG. 7. Even in this case, the shapes of the channel sections of the driver transistors are approximately same. This is because the distances a from the first serif sections 21 and 22 to the driver transistors 1 and 2 are equal to the distances b from the second serif sections 23 and 24 to the driver transistors 1 and 2, respectively. Also, it is because the widths c of the first serif sections 21 and 22 and the widths d of the second serif sections 23 and 24 are same. Therefore, the generation of a transistor characteristic difference in the memory cell can be prevented and the reliability of the memory cell can be kept. In this way, the tolerance of the position alignment displacement is made wide to prevent the generation of the transistor characteristic difference in the memory cell, compared with the conventional case, so that the high integration, fine pattern formation and low power consumption of a semiconductor memory device become easier.

Also, in the layout shown in FIG. 7, the active region 11 is orthogonal to the gate electrode 15 in the neighborhood of the channel region 5, and the active region 12 is orthogonal to the gate electrode 16 in the neighborhood of the channel region 6. By adopting such a structure, even if the position alignment displacement is caused in the direction orthogonal to the gate electrode, the shapes of the channel regions 5 and 6 are same. Therefore, the driver transistor 1 and the driver transistor 2 become approximately identical in characteristic.

Because the semiconductor device according to the first embodiment has the above-mentioned structure, the pair transistors have the same characteristic so that they are excellent in the reliability of the operation, even if the position alignment displacement is caused.

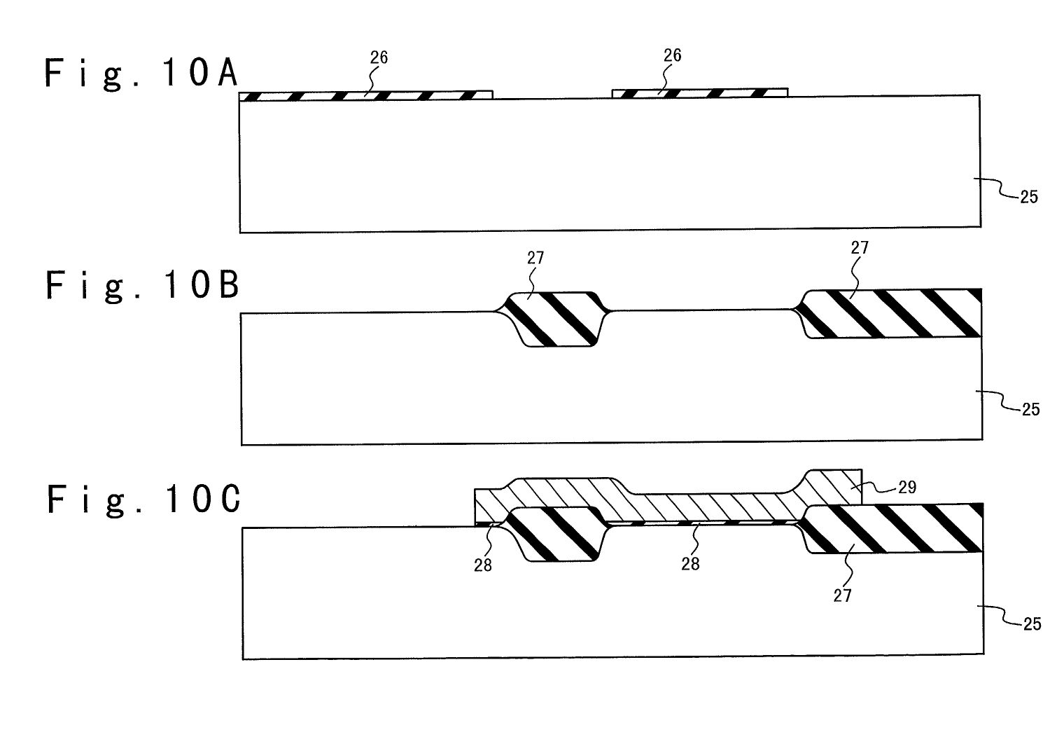

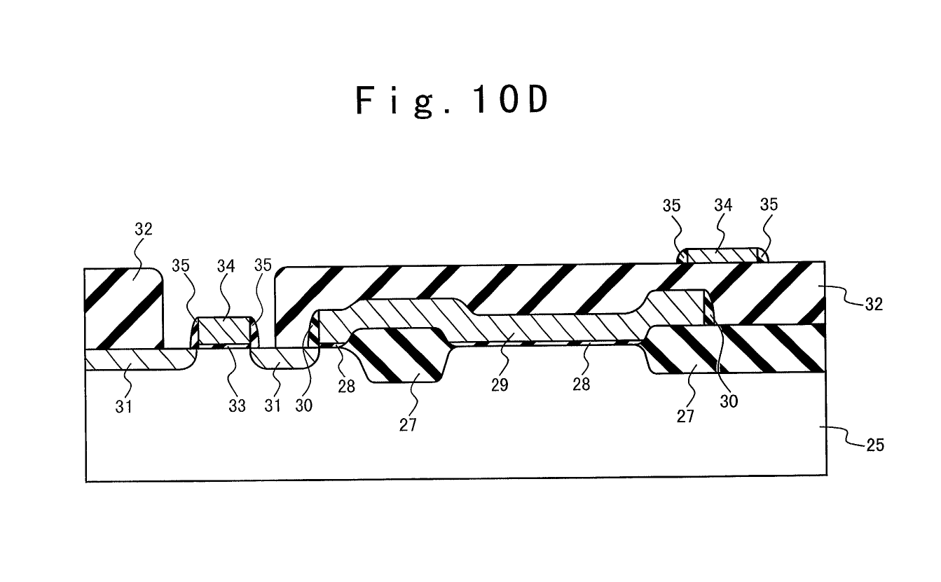

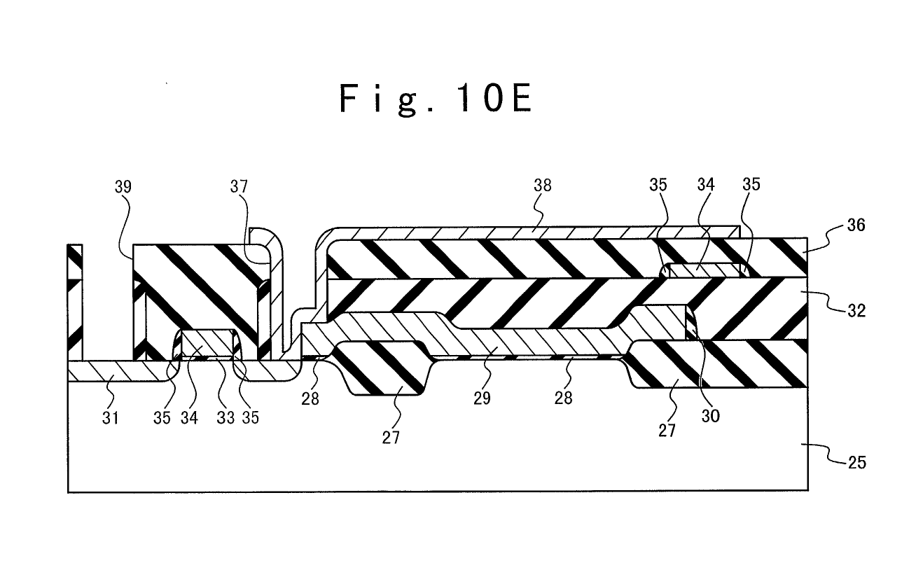

Next, the manufacturing method of the semiconductor device according to the first embodiment will be described below. FIGS. 10A to 10E show cross sectional views of the semiconductor device along the line A-A′ when the semiconductor device is manufactured by the method according to the first embodiment.

First, a SiN film 26 is formed on a substrate 25 in which wells have been formed. The process until the SiN film is formed is the same as a general process used to manufacture a semiconductor device.

Next, a photoresist is left on the SiN film for only a region where the active regions are formed by a photolithography process using a first mask. Thus, a region where the active regions are to be formed is separated from a region where a separation region is to be formed.

Next, the SiN film is removed by an etching process from the region which the separation region is to be formed. The SiN film is left in the region which the active regions are to be formed. The cross sectional structure at this time is shown in of FIG. 10A.

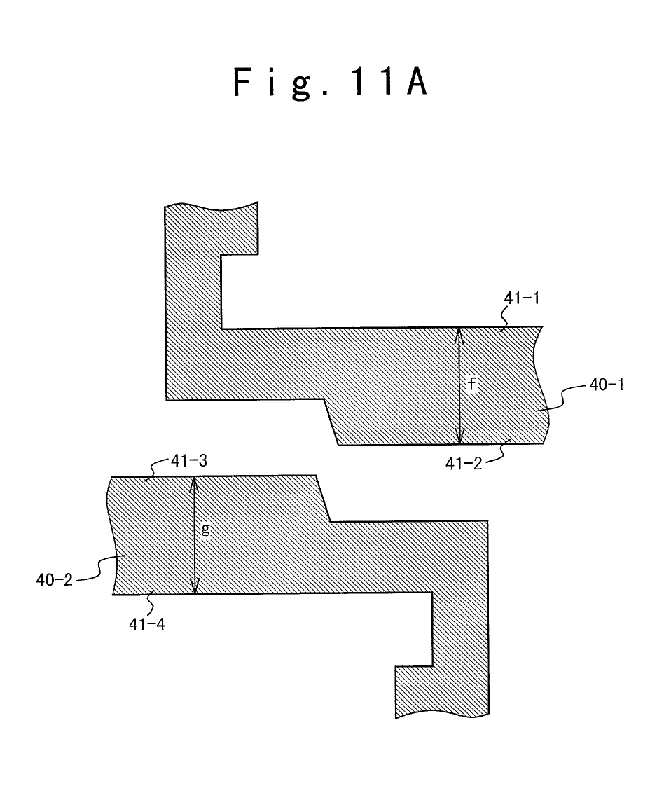

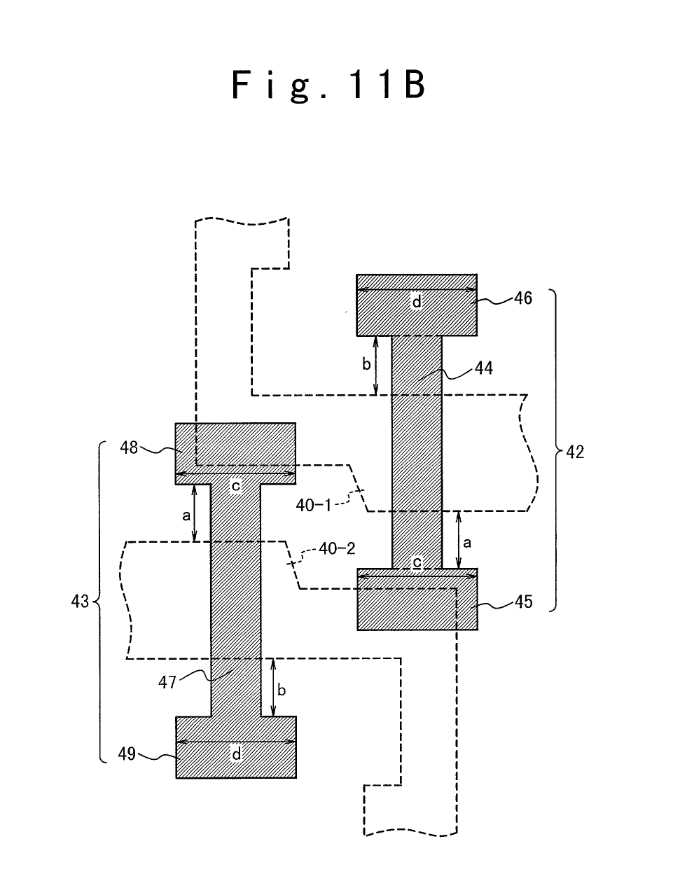

The first mask used to determine the active region and the separation region has a mask layout shown in of FIG. 11A. In FIG. 11A, the regions 40-1 and 40-2 are the separation regions and a region other than the regions 40-1 and 40-2 is the active regions. In FIG. 11A, boundary lines 41-1, 41-2, 41-3 and 41-4 as a part of the boundary lines of the regions 40-1 and 40-2 are parallel to each other. Also, the distance f between the boundary lines 41-1 and 41-2 and the distance g between the boundary lines 41-3 and 41-4 are same. The active regions 11 and 12 are formed to have the same width and to extend the same direction, by use of the first mask having the above-mentioned layout.

Following the etching of the SiN film, the substrate is annealed at a high temperature in oxygen gas. Then, a thermal oxide film 27 is formed in the region where there is no SiN film, i.e., in the separation region. Subsequently, the SiN film left on the active regions is removed. The cross sectional structure of the wafer at this time is shown in Fig. 10B.

Next, a gate oxide film 28 and a first conductive film 29 are formed in order. For example, the first conductive film is formed of polysilicon.

Next, a photoresist is left on the first conductive film in only the region where the gate electrodes of the driver transistors are formed by a photolithography process using a second mask. Subsequently, the first conductive film is etched and the gate electrodes are formed (Fig. 10C).

The mask layout of the second mask used to determine the shape of the first conductive layer is shown in Fig. 11B. To show alignment of the first mask and the second mask, the first mask layout is shown in Fig. 11B by a broken line. The second mask has electrode patterns 42 and 43. The electrode pattern 42 has a gate electrode section 44, a first serif section 45 and a second serif section 46. The electrode pattern 29 has a gate electrode section 47, a first serif section 48 and a second serif section 49. Also, the gate electrode section 44 and the gate electrode section 47 have the same width and extend in the same direction. Also, the first serif section 45 and the second serif section 46 are provided in opposing positions to sandwich the active region 40-1 of the first mask. The first serif section 48 and the second serif section 49 are also provided in opposing positions to sandwich the active region 40-2.

The mask position adjustment is accomplished in the following matters. That is, the widths c of the first serif sections 45 and 48 and the widths d of the second serif sections 46 and 49 are made same. Moreover, the distances a from the first serif sections 45 and 48 to the active regions 40-1 and 40-2 are the same as the distances b from the second serif sections 46 and 49 to the active regions 40-1 and 40-2.

After the gates are formed, the processes of forming sidewalls 30, source/drain regions 31 and an interlayer insulating film 32, and the process of removing the interlayer insulating film from the region which the access transistors are formed are carried out, as in the method of manufacturing a usual semiconductor device.

Then, a gate oxide film 33, a gate electrode 34 composed of a second conductive film, and second sidewalls 35 are formed so that the access transistor is formed (Fig. 10D). After that, an interlayer insulating film 36, a contact 37, a third conductive film 38 and a contact 39 are formed (FIG. 10E).

The subsequent processes such as a process of forming bit lines are the same as the those in the method of manufacturing a usual semiconductor device.

Through the above-mentioned manufacturing method, the semiconductor device can be manufactured to be superior in operation reliability. Also, in the semiconductor device, the characteristic change is difficult to be caused in the pair transistors due to the position alignment displacement.

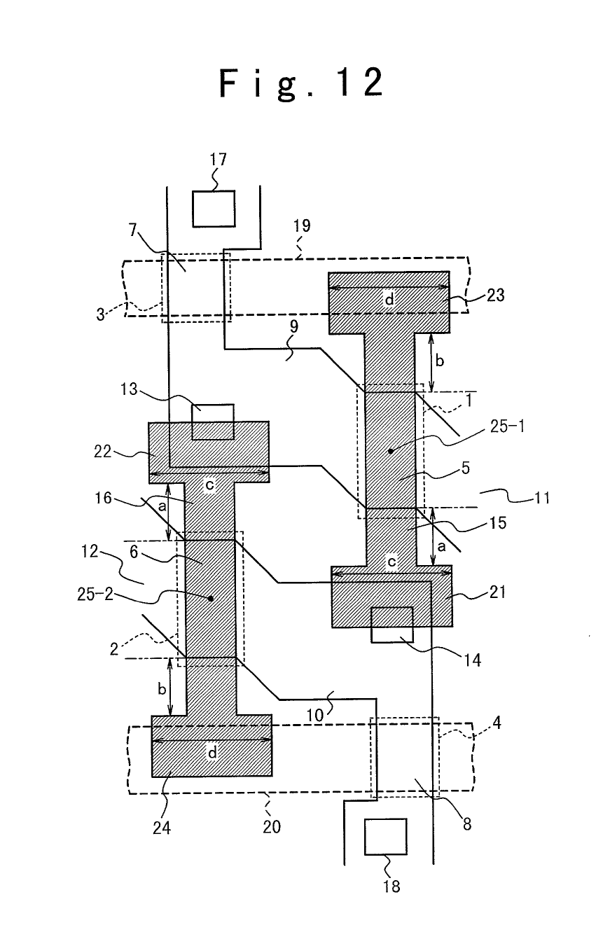

FIG. 12 is a diagram showing a plane layout of the SRAM according to the second embodiment of the present invention. The layout shown in FIG. 12 is different from the layout shown in FIG. 7 in the following points. That is, the active regions 11 and 12 are not orthogonal to the gate electrodes 15 and 16, respectively. The active region 11 has the shape of the point symmetry with respect to the center point 25-1 of the channel region 5. Also, the active region 12 has the shape of the point symmetry with respect to the center point 25-2 of the channel region 6.

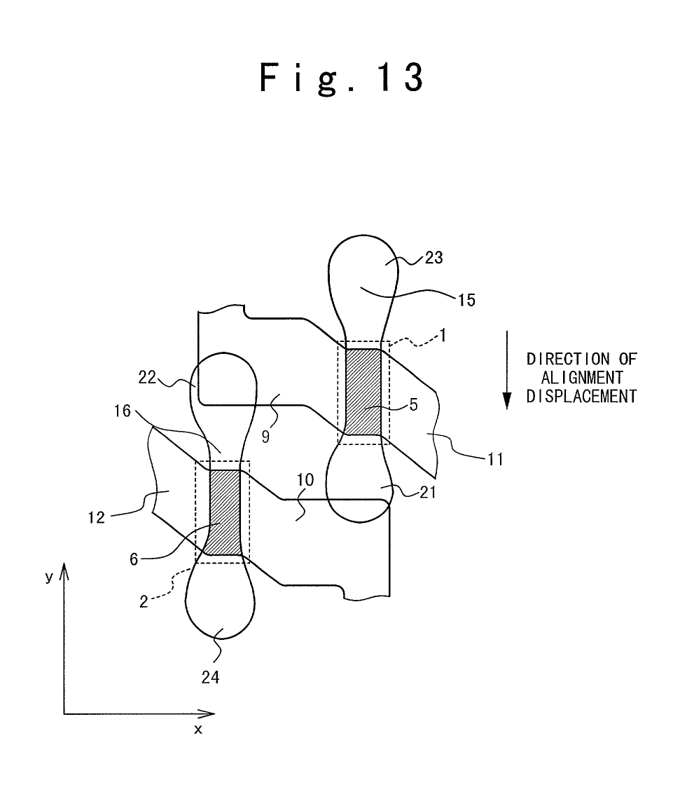

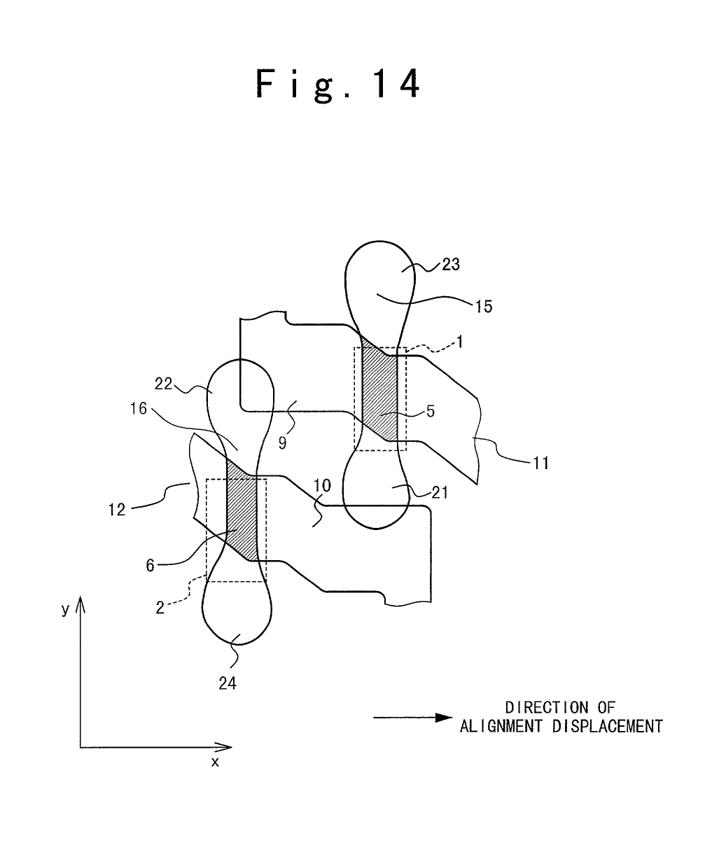

FIG. 13 shows the shape of the SRAM memory cell when the position alignment displacement is caused between the diffusion layers 9 and 10 and the gate electrodes 15 and 16 in the longitudinal direction, i.e., the y direction shown in FIG. 7. In this case, even if the position alignment displacement is caused in the longitudinal direction of the gate electrode in FIG. 12 as in the first embodiment, the shapes of the channel regions 5 and 6 of the driver transistors 1 and 2 can be kept to be same, by using the layout shown in FIG. 12. Also, as shown in FIG. 14, the shapes of channel regions 5 and 6 can be kept to same, even if the position alignment displacement is caused in the perpendicular direction to the gate electrode, i.e., in the x direction in FIG. 13. Thus, it is possible to decrease the region of the layout, compared with the first embodiment. As a result, high integration and fine pattern formation can be made possible.

The manufacturing method of the semiconductor device according to the second embodiment is different in only the shape of the mask layout to determine the active regions and the other processes are the same as those in the first embodiment. Because the semiconductor device according to the second embodiment has above mentioned structure, the pair transistors have the same characteristics, even if the position alignment displacement is caused. Therefore, it is excellent in the reliability of the operation. In addition, the semiconductor device has the structure which is favorable for the high integration and fine pattern formation.

As described above, according to the semiconductor device of the present invention, even if the position alignment displacement is caused between the active region and the gate electrode, it is possible to make the shapes of the channel regions of the pair transistors substantively same. Therefore, the pair transistors can be made identical in characteristics and can be excellent in operation reliability.

Also, because the margin to the position adjustment can be made large, the semiconductor device is easier in the high integration, fine pattern formation and low power consumption.

Also, according to the manufacturing method of the semiconductor device of the present invention, even if the position alignment displacement is caused between the active region and the gate electrode, the shapes of the channel regions of the pair transistors can be substantively same. As a result, the semiconductor device that the operation is stable can be manufactured.

Also, when the present invention is applied to the memory cell of an SRAM, the flip-flop can be formed to symmetrically operate, resulting in the stable operation in the SRAM.

What is claimed is:

1. A semiconductor device comprising:
first and second transistors to be arranged a point symmetry with respect to a point and having first and second gates and first and second channel regions, respectively,
wherein said first and second gates are formed based on first and second gate electrode patterns to be arranged a point symmetry with respect to the point, respectively, and
each of said first and second gate electrode patterns includes first and second serif sections and an electrode section between said first and second serif sections.

2. A semiconductor device according to claim 1, wherein said first and second electrode sections have substantially a same width in a direction perpendicular to a longitudinal direction of each of said first and second gate electrode patterns.

3. A semiconductor device according to claim 2, wherein a distance from said first serif section to said first channel region in said first gate electrode pattern is substantially the same as a distance from said first serif section to said second channel region in said second gate electrode pattern.

4. A semiconductor device according to claim 3, wherein a distance from said second serif section to said first channel region in said first gate electrode pattern is substantially the same as a distance from said second serif section to said second channel region in said second gate electrode pattern.

5. A semiconductor device according to claim 2, wherein said first serif section and said second serif section have substantially the same width in each of said first and second gate electrode patterns.

6. A semiconductor device according to claim 2, wherein said first serif section and said second serif section have substantially the same shape in each of said first and second gate electrode patterns.

7. A static random the access memory comprising:
a flip-flop including first and second transistors electrically cross-connected, and
wherein said first and second transistors are arranged a point symmetry with respect to a point and have first and second gates and first and second channel regions, respectively,
said first and second gates are formed based on first and second gate electrode patterns to be arranged a point symmetry with respect to the point, respectively,
each of said first and second gate electrode patterns includes first and second serif sections and an electrode section between said first and second serif sections, and
said first serif in one of said first and second transistors corresponding to one of said first and second gate electrode patterns is connected to a source/drain region of the other of said first and second transistors.

8. A semiconductor device according to claim 7, wherein said first and second electrode sections have substantially a same width in a direction perpendicular to a longitudinal direction of each of said first and second gate electrode patterns.

9. A semiconductor device according to claim 8, wherein a distance from said first serif section to said first channel region in said first gate electrode pattern is substantially the same as a distance from said first serif section to said second channel region in said second gate electrode pattern.

10. A semiconductor device according to claim 9, wherein a distance from said second serif section to said first channel region in said first gate electrode pattern is substantially the same as a distance from said second serif section to said second channel region in said second gate electrode pattern.

11. A semiconductor device according to claim 8, wherein said first serif section and said second serif section have substantially the same width in each of said first and second gate electrode patterns.

12. A semiconductor device according to claim 8, wherein said first serif section and said second serif section have substantially the same shape in each of said first and second gate electrode patterns.

13. A method of manufacturing a semiconductor devices, comprising:
forming a first and second diffusion regions on a semiconductor substrate using a first mask;
forming an insulating film on said semiconductor substrate as a gate insulating film; and
forming first and second gate electrodes patterns using a second mask such that first and second transistors are formed based on said first and second gate electrodes patterns and said first and second diffusion regions, respectively,
wherein each of said first and second gate electrode patterns includes first and second serif sections and an electrode section between said first and second serif sections.

14. A method according to claim 13, further comprising connecting said first serif in one of said first and second transistors corresponding to one of said first and second gate electrode patterns to a source/drain region of the other of said first and second transistors.

15. A method according to claim 13, wherein said first and second electrode sections have substantially a same width in a direction perpendicular to a longitudinal direction of each of said first and second gate electrode patterns.

16. A method according to claim 15, wherein a distance from said first serif section to said first channel region in said first gate electrode pattern is substantially the same as a distance from said first serif section to said second channel region in said second gate electrode pattern.

17. A method according to claim 16, wherein a distance from said second serif section to said first channel region in said first gate electrode pattern is substantially the same as a distance from said second serif section to said second channel region in said second gate electrode pattern.

18. A method according to claim 16, wherein said first serif section and said second serif section have substantially the same width in each of said first and second gate electrode patterns.

19. A method according to claim 15, wherein said first serif section and said second serif section have substantially the same shape in each of said first and second gate electrode patterns.
